(19) United States
(12) Patent Application Publication
(10) Pub. No.: US 2026/0057146 A1
(43) Pub. Date: Feb. 26, 2026

(54) CHARGE-TRANSFER-BASED MACHINE-LEARNED INTERATOMIC POTENTIALS FOR SCALABLE, AUGMENTED HAMILTONIANS

(71) Applicant: Robert Bosch GmbH, Stuttgart (DE)

(72) Inventors: Mordechai KORNBLUTH, Brighton, MA (US); Daniil KITCHAEV, Brookline, MA (US); Nicola MOLINARI, Cambridge, MA (US); Karim GADELRAB, Boston, MA (US)

(21) Appl. No.: 18/813,846

(22) Filed: Aug. 23, 2024

(51) Int. Cl. G06F 30/27; G06N 20/00

(52) U.S. Cl. CPC G06F 30/27; G06N 20/00

(57) ABSTRACT

Methods for a machine learning network that trains and subsequently executes one or more machine learning (ML) models are disclosed. The system described herein is configured to embed atomic positions and species of a given atomic system and apply those to ML model(s) to learn charge transfer properties and local energies. By constructing atomic charges from learned charge transfer properties, both local and global charge neutrality is ensured. The atomic charges are then used to generate an auxiliary Hamiltonian description. By combining both the auxiliary Hamiltonian description and the learned local energies, properties such as total energy of the atomic system are determined. By determining total energy from the auxiliary Hamiltonian description and the learned local energies, such methods ensure that long and short range effects are accounted for, while also appropriately enabling for realistic discontinuities and/or transitions within the potential energy surface.

### TECHNICAL FIELD

The present disclosure relates to training and executing one or more machine learning models to learn charge transfer within a context of machine-learning interatomic potentials.

### BACKGROUND

Various machine learning techniques have proven useful within a context of predicting interaction energies, forces, and other properties of various systems. However, there is a non-trivial balancing of the usage of a given machine learning model for large-scale systems while also taking into account short-range effects and transitions (e.g., a magnetic transition). Providing scalable machine learning techniques for implementation into iterative processes, such as molecular dynamics, remains a challenge.

### SUMMARY

In contrast to previous implementations of machine-learning interatomic potentials (MLIPs) that use machine learning (ML) to learn atomic charges of a given atomic system, the present disclosure utilizes one or more ML models to determine charge transfers, which are then used to construct atomic charges for the atomic system. The atomic charges can then be used to determine other properties of an atomic system, such as the total energy in the system. The ML model(s) learn both charge transfer properties and local energies of the atomic system, thus ensuring that the particular MLIP architecture is scalable, and can be implemented into larger-scale simulations, such as molecular dynamics, and with accuracy similar to that of ab-initio methods. Moreover, by learning charge transfer and using the learned charge transfers to compute atomic charges, the resulting auxiliary Hamiltonian description, and additional properties such as the total energy, ensure both local and global charge neutrality within the atomic system.

### BRIEF DESCRIPTION OF THE DRAWINGS

FIG. 1 illustrates a system for training and utilizing a machine learning model, such as a neural network, according to some embodiments.

FIG. 2 illustrates a computer-implemented method for training and utilizing a machine learning model, such as a neural network, according to some embodiments.

FIG. 3 illustrates a high-level workflow diagram for machine-learning interatomic potentials of a given atomic system, according to some embodiments.

FIG. 4 illustrates an extension of the high-level workflow diagram introduced in FIG. 3, wherein backpropagation is used to determine related forces of the given atomic system, according to some embodiments.

FIG. 5 illustrates a workflow diagram for a machine-learning-based energy determination within the context of machine-learning interatomic potentials of an atomic system, according to some embodiments.

FIG. 6 illustrates another workflow diagram for a machine-learning-based energy determination within the context of machine-learning interatomic potentials of an atomic system, according to some embodiments.

FIG. 7 illustrates yet another workflow diagram for a machine-learning-based energy determination within the context of machine-learning interatomic potentials of an atomic system, according to some embodiments.

FIG. 8 illustrates an example implementation of applying a machine-learning-based energy determination to a scenario of corrosion of steel, according to some embodiments.

FIG. 9 is a flow diagram that illustrates a process of executing one or more machine learning models to learn charge transfers of an atomic system, and applying the learned charge transfers to determine long and short range effects of the atomic system, according to some embodiments.

FIG. 10 is a flow diagram that illustrates an iterative, molecular-dynamics-based processing, according to some embodiments.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative bases for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical application. Various combinations and modifications of the features consistent with the teachings of this disclosure, however, could be desired for particular applications or implementations.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions.

Applications of machine-learned interatomic potentials (MLIP) are vast and diversified. However, until the development of the present disclosure, past implementations of MLIP compromised either (1) the ability to scale while including interactions beyond a restricted number of neighbor atoms, (2) the ability to learn long-range effects, and/or (3) the ability to account for discontinuities and/or transitions. When using MLIP to compute energy and forces, it is important to have the flexibility to incorporate all three of those abilities, depending upon a given type of atomic system, and for a more complete and comprehensive analysis. The following few paragraphs detail the context for each of these challenges that were faced by past implementations of MLIP, following by an explanation of how the present disclosure overcomes the need to prioritize one of these effects to the detriment of one or more of the other effects.

In terms of the ability to scale beyond a restricted number of neighbor atoms, past implementations of MLIP were unable to overcome the difficulty of scaling deep learning networks, especially for very large atomic systems. In the past, deep neural networks would take a cutoff of neighbor atoms re, where information in the deep neural network would then be passed only between atoms within the fixed cutoff distance. Even further limiting was that the common message-passing deep neural networks, such as Nequip, applied this cutoff distance at each level of the deep neural network, such that a given deep neural network with N layers has an effective cutoff of Nr_{c} and a number of effective neighboring atoms that scales as (Nr_{c})³. This (Nr_{c})³ type scaling makes it nearly impossible to partition the atoms in a given atomic system across different processors during a given production run, as is typically of interest to do with large-scale simulation techniques such as molecular dynamics. In addition, the (Nr_{c})³ type scaling is computationally cubically expensive, as the number of atoms increases with the cube of N. This lack of ability to scale was still not resolved, even with techniques such as Allegro, which partitions the energy into a per-atom energy Eᵢ=Σ_{jENi} Eᵢⱼ(Nᵢ), wherein Nᵢ is the set of all atoms in the neighborhood of i (i.e. within the cutoff), and no others, and wherein Eᵢⱼ is an effective pairwise energy corresponding to two atoms i and j.

In terms of the ability to learn long-range effects, such as electrostatics and delocalized electrons (e.g., magnetic conductors), past implementations of MLIP, again such as Allegro which is limited to purely local energies, were unable to overcome this difficulty. Energies and forces associated with long-range effects may be strongly affected by longer-range interactions within an atomic system than what can be captured within a cutoff radius re, which is typically several Angstroms. This led to either enormously increasing the value of re, which in turn then leads to increasing instabilities, computation time, and/or memory requirements, or to have long-range effects to be neglected completely, which in turn then leads to a significant loss in accuracy of the given simulation. By focusing on interactions within a neighborhood of some central atom i, the analysis of long-range interaction (e.g., the interaction between central atom i and another atom beyond the cutoff radius rc) is lost.

Even when using an auxiliary network to learn electrostatic point charges using density functional theory (DFT) datasets, which can then be input into a well-known method for computing long-range electrostatic forces and energies (e.g., an Ewald summation), there previously lacked a comprehensive method for incorporating both short-range and long-range effects into a given type of simulation. Other attempts included fitting point charges to DFT-based charges, such as by using Hirshfeld or Mulliken charge partitioning schemes, or deriving effective charge values from other quantities, such as fitting only to the total energy while not accounting for local energies.

None of such attempts addressed the problem of enabling the ability to scale while also enabling the ability to stably incorporate long-range effects. In particular, a serious drawback of such previous methods in the prior art is that atomic charges can fluctuate often and considerably, and therefore the entire potential energy surface may be extremely sensitive to the initial configuration of the simulation, as well as to small perturbations in the atomic positions over the course of the simulation. Moreover, overall charge neutrality must be enforced at all times, e.g., Σᵢqᵢ=Qₜₒₜₐₗ, where Qₜₒₜₐₗ is the total charge of the atomic system and sums to 0. Enforcing the neutrality constraint means that the charge update cannot be done locally, without considering all atoms in the atomic system. Put together, the sensitivity of the charge values to precise atomic configurations and the need to enforce charge neutrality made it previously impossible to partition the atomic system into purely-local components and efficiently proceed with the molecular dynamics simulation.

In terms of the ability to account for discontinuities and/or transitions, previous applications of MLIP did not effectively capture discontinuities in the potential energy surface. Often there are segments of the potential energy surface that are smooth with respect to atomic position, and other segments that correspond to a transition (e.g. a magnetic transition, a bond breaking, charge transfer) where there should be an abrupt change in the potential energy surface. Past applications of MLIP failed to target a transition that would make the potential energy surface discontinuous, while also allowing for the potential energy surface to be continuously differentiable and reasonably smooth (and therefore stable) in each region, due to the abrupt change of the given transition.

In order to address these challenges, the present disclosure has engineered a machine learning network to learn both charge transfers and local energies of a given atomic system. Rather than directly learning atomic charges, the machine learning model is provided with the atomic positions and species of the atomic system and is executed in order to learn charge transfers. The learned charge transfers are then used to construct atomic charges. By training and executing a machine learning model that learns charge transfer properties and building upwards from there, the resulting atomic charges, auxiliary Hamiltonian description, and other macro-level properties such as total energy and forces are ensured to have both local and global charge neutrality by construction.

In parallel to this, the atomic positions and species of the atomic system may also be used as input to either the same or another machine learning model, such as a deep neural network, in order to learn local energies.

The combination of both the auxiliary Hamiltonian description and the learned local energies allows the particular MLIP architectures described herein to determine a total energy of a given atomic system with high precision and while addressing the three challenges previously faced by the scientific community that are described above.

The following description continues with a general introduction to machine learning techniques that are relevant to the methods for machine-learning interatomic potentials described herein. Next, various embodiments of machine learning model based architectures are discussed. The present disclosure then demonstrates the versatility of the methods and systems described herein for use in determining macro and micro-level properties of various molecular compositions and in implementation into larger-scale simulations, such as molecular dynamics (MD).

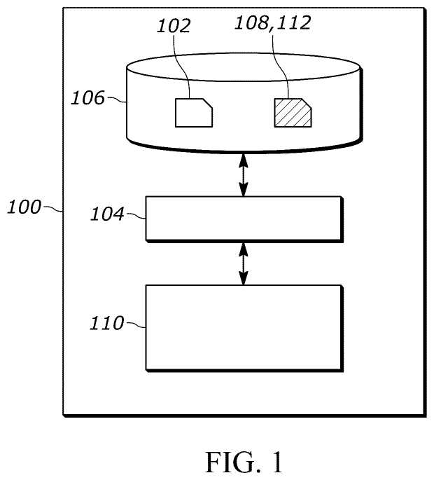

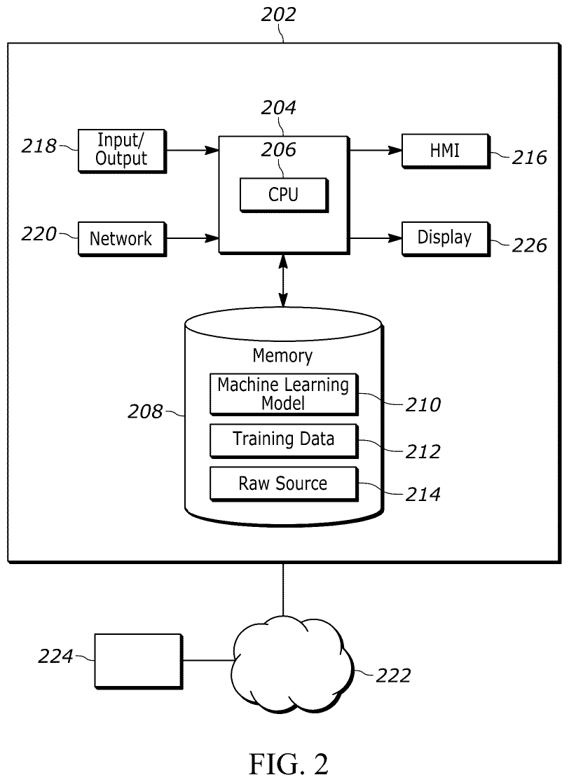

FIG. 1 illustrates a system 100 for training and utilizing a neural network, such as a deep neural network. It should be understood that, while the example embodiments given in the following paragraphs herein with regard to FIGS. 1 and 2 refer to a deep neural network, additional embodiments of FIGS. 1 and 2 may be applied to any other type of neural-network-based or non-neural-network-based machine learning model (e.g., Gaussian processes) that is configured to be developed, trained, and optimized for various machine-learned interatomic potentials applications.

Moreover, and as related to the description herein, a “deep” learning model, such as a deep neural network, may be defined as having multiple hidden layers (e.g., one, two, or tens of hidden layers) in between an input layer and an output layer of the model. A deep learning model may additionally be used to describe a machine learning model that is configured to learn complex patterns and representations based on training and/or validation datasets that are used as inputs to the deep learning model. Additional embodiments pertaining to such types of machine learning models are described herein with regard to machine learning model 210, network 306, network 406, networks 506 and 520, networks 606 and 620, network 706, and blocks 906 and 910.

In some embodiments, the system 100 may comprise an input interface for accessing training data 102 for the neural network. For example, as illustrated in FIG. 1, the input interface may be constituted by a data storage interface 104 which may access the training data 102 from a data storage 106. For example, the data storage interface 104 may be a memory interface or a persistent storage interface, e.g., a hard disk or an SSD interface, but also a personal, local or wide area network interface such as a Bluetooth, ZigBee or Wi-Fi interface or an Ethernet or fiber optic interface. The data storage 106 may be an internal data storage of the system 100, such as a hard drive or SSD, but also an external data storage, e.g., a network-accessible data storage.

In some embodiments, the data storage 106 may further comprise a data representation 108 of an untrained version of the model (e.g., a version of the machine learning model that has yet to be trained) which may be accessed by the system 100 from the data storage 106. It will be appreciated, however, that the training data 102 and the data representation 108 of the untrained neural network may also each be accessed from a different data storage, e.g., via a different subsystem of the data storage interface 104. Each subsystem may be of a type as is described above for the data storage interface 104. In other embodiments, the data representation 108 of the untrained neural network may be internally generated by the system 100 on the basis of design parameters for the neural network, and therefore may not explicitly be stored on the data storage 106. The system 100 may further comprise a processor subsystem 110 which may be configured to, during operation of the system 100, provide an iterative function as a substitute for a stack of layers of the neural network to be trained. Here, respective layers of the stack of layers being substituted may have mutually shared weights and may receive, as input, an output of a previous layer, or for a first layer of the stack of layers, an initial activation, and a part of the input of the stack of layers. The processor subsystem 110 may be further configured to iteratively train the neural network using the training data 102 (e.g., thus generating updated versions of the machine learning model with respect to a first “untrained” version of the model). Here, an iteration of the training by the processor subsystem 110 may comprise a forward propagation part and a backward propagation part. The processor subsystem 110 may be configured to perform the forward propagation part by, amongst other operations defining the forward propagation part which may be performed, determining an equilibrium point of the iterative function at which the iterative function converges to a fixed point, wherein determining the equilibrium point comprises using a numerical root-finding algorithm to find a root solution for the iterative function minus its input, and by providing the equilibrium point as a substitute for an output of the stack of layers in the neural network. The system 100 may further comprise an output interface for outputting a data representation 112 of the trained neural network, this data may also be referred to as trained model data 112. For example, as also illustrated in FIG. 1, the output interface may be constituted by the data storage interface 104, with said interface being in these embodiments an input/output (“IO”) interface, via which the trained model data 112 may be stored in the data storage 106. For example, the data representation 108 defining the ‘untrained’ neural network may during or after the training be replaced, at least in part by the data representation 112 of the trained neural network, in that the parameters of the neural network, such as weights, hyperparameters, and other types of parameters of neural networks, may be adapted to reflect the training on the training data 102. This is also illustrated in FIG. 1 by the reference numerals 108 and 112 referring to the same data record on the data storage 106. In other embodiments, the data representation 112 may be stored separately from the data representation 108 defining the ‘untrained’ neural network. In some embodiments, the output interface may be separate from the data storage interface 104, but may in general be of a type as described above for the data storage interface 104.

FIG. 2 illustrates a computer-implemented method for training and utilizing a neural network, according to some embodiments. The system 200 may include at least one computing system 202. The computing system 202 may include at least one processor 204 that is operatively connected to a memory unit 208. The processor 204 may include one or more integrated circuits that implement the functionality of a central processing unit (CPU) 206 and, in some embodiments, a graphics processing unit (GPU). The CPU 206 may be a commercially available processing unit that implements an instruction set such as one of the x86, ARM, Power, or MIPS instruction set families. During operation, the CPU 206 may execute stored program instructions that are retrieved from the memory unit 208. The stored program instructions may include software that controls operation of the CPU 206 to perform the operation described herein. In some examples, the processor 204 may be a system on a chip (SoC) that integrates functionality of the CPU 206, the memory unit 208, a network interface, and input/output interfaces into a single integrated device. The computing system 202 may implement an operating system for managing various aspects of the operation.

The memory unit 208 may include volatile memory and non-volatile memory for storing instructions and data. The non-volatile memory may include solid-state memories, such as NAND flash memory, magnetic and optical storage media, or any other suitable data storage device that retains data when the computing system 202 is deactivated or loses electrical power. The volatile memory may include static and dynamic random-access memory (RAM) that stores program instructions and data. For example, the memory unit 208 may store a machine learning model 210 or algorithm, a training dataset 212 for the machine learning model 210 (e.g., density functional theory (DFT) training datasets), raw source dataset 214, etc.

The computing system 202 may include a network interface device 220 that is configured to provide communication with external systems and devices. For example, the network interface device 220 may include a wired and/or wireless Ethernet interface as defined by Institute of Electrical and Electronics Engineers (IEEE) 802.11 family of standards. The network interface device 220 may include a cellular communication interface for communicating with a cellular network (e.g., 3G, 4G, 5G). The network interface device 220 may be further configured to provide a communication interface to an external network 222 or cloud.

The external network 222 may be referred to as the world-wide web or the Internet. The external network 222 may establish a standard communication protocol between computing devices. The external network 222 may allow information and data to be easily exchanged between computing devices and networks. One or more servers 224 may be in communication with the external network 222.

The computing system 202 may include an input/output (I/O) interface 218 that may be configured to provide digital and/or analog inputs and outputs. The I/O interface 218 may include additional serial interfaces for communicating with external devices (e.g., Universal Serial Bus (USB) interface).

The computing system 202 may include a human-machine interface (HMI) device 216 that may include any device that enables the system 200 to receive control input. Examples of input devices may include human interface inputs such as keyboards, mice, touchscreens, voice input devices, and other similar devices. The computing system 202 may include a display device 226. The computing system 202 may include hardware and software for outputting graphics and text information to the display device 226. The display device 226 may include an electronic display screen, projector, printer or other suitable device for displaying information to a user or operator. The computing system 202 may be further configured to allow interaction with remote HMI and remote display devices via the network interface device 220.

The system 200 may be implemented using one or multiple computing systems. While the example depicts a single computing system 202 that implements all of the described features, it is intended that various features and functions may be separated and implemented by multiple computing units in communication with one another. The particular system architecture selected may depend on a variety of factors.

The system 200 may implement a machine learning algorithm 210 that is configured to analyze the raw source dataset 214. The raw source dataset 214 may include raw or unprocessed sensor data that may be representative of an input dataset for a machine learning system. The raw source dataset 214 may include DFT training datasets and/or any other atomic descriptions relating to atomic positions and atomic species of various systems. In some examples, the machine learning algorithm 210 may be a neural network algorithm that is designed to perform a predetermined function. For example, the neural network algorithm may be configured within a context of machine-learning interatomic potentials to learn local energies of a system.

The computer system 200 may store a training dataset 212 for the machine learning algorithm 210. The training dataset 212 may represent a set of previously constructed data for training the machine learning algorithm 210. The training dataset 212 may be used by the machine learning algorithm 210 to learn weighting factors associated with a neural network algorithm. The training dataset 212 may include a set of source data that has corresponding outcomes or results that the machine learning algorithm 210 tries to duplicate via the learning process. In a context of machine-learning interatomic potentials, machine learning algorithm 210 may predict energies and/or other atomic properties of a given atomic system.

The machine learning algorithm 210 may be operated in a learning mode using the training dataset 212 as input. The machine learning algorithm 210 may be executed over a number of iterations using the data from the training dataset 212. With each iteration, the machine learning algorithm 210 may update internal weighting factors based on the achieved results. For example, the machine learning algorithm 210 can compare output results (e.g., annotations) with those included in the training dataset 212. Since the training dataset 212 includes the expected results, the machine learning algorithm 210 can determine when performance is acceptable. After the machine learning algorithm 210 achieves a predetermined performance level (e.g., 100% agreement with the outcomes associated with the training dataset 212), the machine learning algorithm 210 may be executed using data that is not in the training dataset 212. The trained machine learning algorithm 210 may be applied to new datasets to generate annotated data.

The machine learning algorithm 210 may be configured to identify a particular feature in the raw source data 214. The raw source data 214 may include a plurality of instances or input dataset for which annotation results are desired. The machine learning algorithm 210 may be programmed to process the raw source data 214 to identify the presence of the particular features. The machine learning algorithm 210 may be configured to identify a feature in the raw source data 214 as a predetermined feature (e.g., an atomic system comprising water molecules has evidence of hydrogen and oxygen). The raw source data 214 may be derived from a variety of sources. For example, the raw source data 214 may be actual input data collected by a machine learning system. The raw source data 214 may be machine generated for testing the system. As an example, the raw source data 214 may include DFT training datasets related to different concentrations of salt that has led to corrosion of steel.

In the example, the machine learning algorithm 210 may then process raw source data 214 and output an indication of predicted local energies. A machine learning algorithm 210 may generate a confidence level or factor for each output generated. For example, a confidence value that exceeds a predetermined high-confidence threshold may indicate that the machine learning algorithm 210 is confident that the identified feature corresponds to the particular feature. A confidence value that is less than a low-confidence threshold may indicate that the machine learning algorithm 210 has some uncertainty that the particular feature is present.

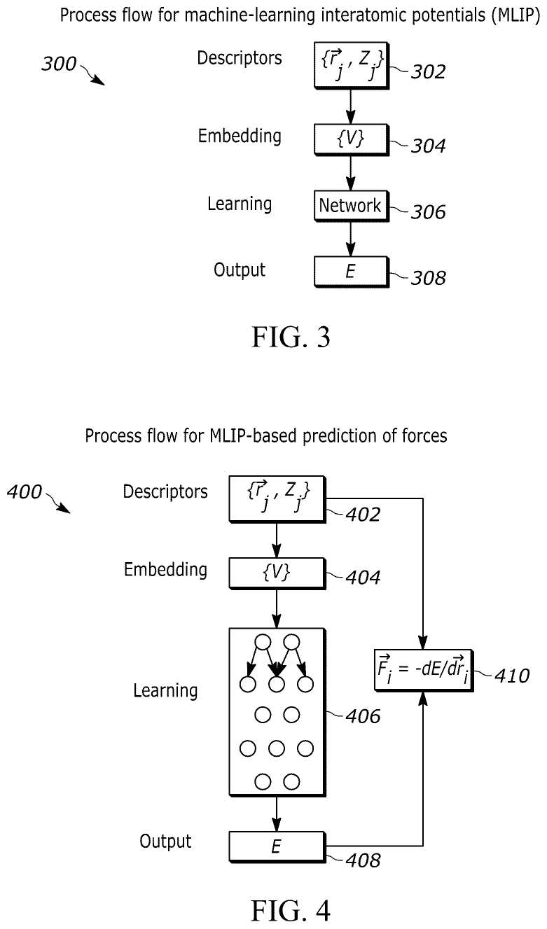

FIG. 3 illustrates a high-level workflow diagram for MLIP of a given atomic system, according to some embodiments.

In some embodiments, MLIP, as used and described herein, may be used to map a set of atomic positions, {\vec{r}ᵢ}, and corresponding atomic species, {Zᵢ}, of a given atomic system to a scalar energy, E, as shown in FIG. 3, and, by extension, to additional properties such as forces {Fᵢ}, as shown in FIG. 4. In some embodiments, this may be considered to be an equivalent to learning the potential energy surface of the atomic system.

As applied herein, atomic species may refer to atomic number, isotope, an elemental description, or any other property that is used to distinguish different atomic identities over the simulation.

As shown in process 300, atomic positions and atomic species may be referred to as atomic descriptors 302, or to an atomic description 302. For example, in some embodiments in which process 300 resembles a process flow that is being fulfilled for a customer, the customer may provide a request to determine the total energy of a given atomic system, and then provide an atomic description 302 to the computing system that is operating the method shown in FIG. 3. It should similarly be understood that the atomic positions and atomic species within atomic descriptors 302 refers to data that, when compiled, provides a simulated atomic structure of the atomic system, based on the provided atomic positions and atomic species.

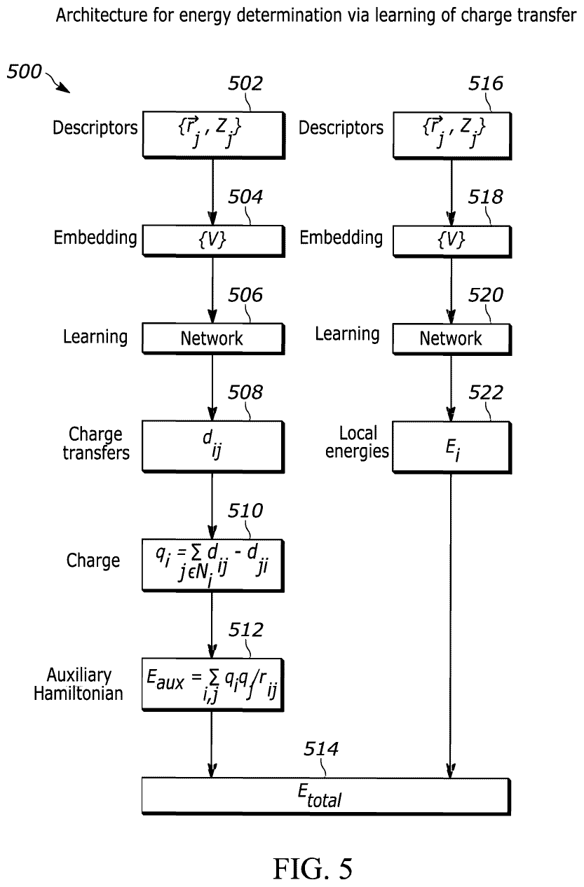

Embedding 304 refers to the conversion of the atomic positions and species into inputs for the interatomic potentials, which are denoted as {V} in the figure. These inputs for the interatomic potentials are also referred to herein as atomic descriptors. The embeddings may be designed to be invariant or covariant with respect to certain symmetry groups of the atomic system or of physics, such as translation, rotation, exchange of atoms, or various crystal symmetries. Such an embedding is additionally discussed with regard to FIGS. 5, 6, and 7 herein. Embedding 304 is then provided as an input to “network” 306, wherein the learning of one or more properties about the atomic system takes place. FIGS. 3 and 4 are designed to demonstrate an overall process flow of MLIP, while FIGS. 5, 6, and 7 will illustrate the use of one or more machine learning models during the learning 306 stage.

The one or more properties learned during the learning 306 stage are then used to calculate a total energy of the atomic system, which is also referred to as output 308 in FIG. 3.

Process 300 may be applied to various computational simulations, such as those that reconstruct structures from experimental data, molecular dynamics simulations, methods for finding a particular atomic configuration for an atomic system, atomic Monte Carlo or grand canonical Monte Carlo simulations, and even for simulations that identify likely reactions and/or transition states.

FIG. 4 illustrates an extension of the high-level workflow diagram introduced in FIG. 3, wherein backpropagation is used to determine related forces of the given atomic system, according to some embodiments.

Similarly to that which was introduced in FIG. 3, process 400 depicts a set of atomic positions and atomic species that are embedded into atomic descriptors 402 during the embedding 404 stage. Then, one or more machine learning models are applied during learning 406 stage in order to determine the total energy of an atomic system, as shown by output 408.

As additionally illustrated in FIG. 4, learning 406 refers to a deep neural network. A deep neural network typically has several layers that are learned using backpropagation, wherein the weights of the network are optimized to minimize a loss function such as L=|E_{pred}−E_{actual}|², and wherein E_{actual} are the training data extracted from a higher-fidelity method, such as DFT. Backpropagation may also be referred to as backpropagation through the network model, wherein weights of the network are adjusted based on the model's error rate. An example of a technique that applies backpropagation is pytorch's autograd functionality.

In some embodiments, backpropagation may also be used to predict forces, denoted as forces 410 in FIG. 4, as the derivative of the total energy with respect to atomic positions. The deep neural network may then also be further trained on forces using a loss function such as L=Σᵢ|\vec{F}i,pred−\vec{F}_{i,actual}|², and again using high-fidelity forces, such as that of DFT. The loss function may also focus on the stress tensor, or a combination of two or more of the above, according to some embodiments.

Particular embodiments illustrated in FIG. 4 refer to learning 406 as being implemented using a deep neural network (e.g., Nequip, Allegro) in order to determine both a total energy and forces using backpropagation. However, other embodiments of process 400 may refer to learning 406 as being implemented using one or more Gaussian processes (e.g., FLARE). As utilized herein, one or more Gaussian processes may refer to the use of one or more of such processes that, when combined, implement a model. The model may then be referred to as a Gaussian process model, or a Gaussian-based model.

Depending upon a particular implementation of process 300 and 400 for a given problem statement provided by a customer, it should be understood that learning 306 and 406 may be customized to refer to a deep neural network or to one or more Gaussian processes. Furthermore, Gaussian processes and deep neural networks may be defined as the two main classes of MLIP. Thus, workflow diagrams illustrated in all figures and their corresponding text herein are meant to refer to MLIP implementations that include those that are using either Gaussian processes or deep neural networks, depending up the given implementation of the present disclosure.

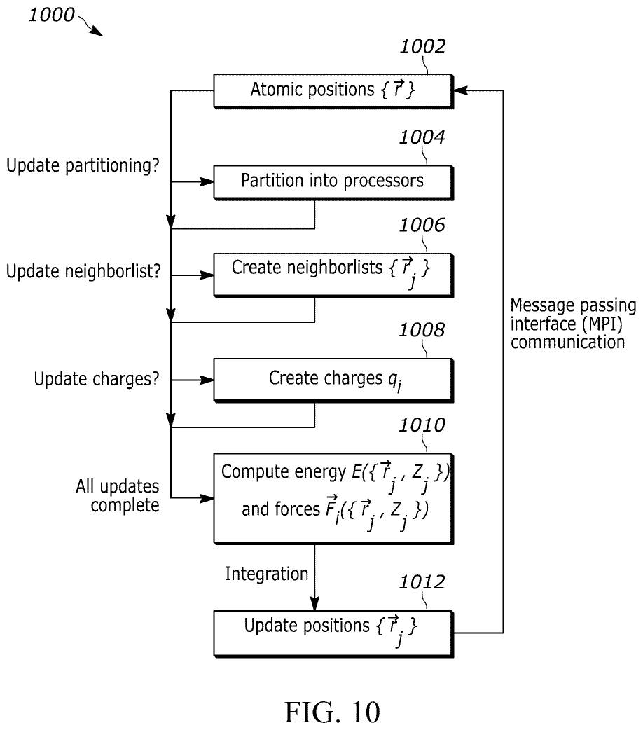

Moreover, an example embodiment of a molecular dynamics algorithm using the type of approach depicted in FIG. 4 is additionally illustrated in FIG. 10.

FIG. 5 illustrates a workflow diagram for a machine-learning-based energy determination within the context of machine-learning interatomic potentials of an atomic system, according to some embodiments.

As introduced above, the following architectures described in FIGS. 5, 6, and 7 herein ensure that both short-range and long-range effects are appropriately captured within a total energy description of an atomic system, and that both local and global charge neutrality is ensured due to locality by construction. In addition, rather than executing one or more machine learning models to learn atomic charges of the atomic system, a given machine learning model is configured to learn charge transfer of the atomic system. This also contributes to the ability to ensure both local and global charge neutrality.

Moreover, such methods of learning charge transfer instead of learning atomic charges directly is of particular relevance for applications in which short-range and/or long-range electrostatic effects are of particular interest or concern.

As illustrated in architecture 500, atomic descriptors 502 include information pertaining to an atomic description of the atomic system, such as atomic positions and atomic species. In some embodiments, atomic descriptors 502 are local in a sense that they includes reference to atoms j within a neighborhood of a central atom i.

Atomic descriptors 502 are then embedded as inputs for the interatomic potentials, as illustrated in embedding 504.

The embedded atomic descriptors are then provided to a first machine learning model 506, wherein the first machine learning model 506 is executed in order to learn charge transfers 508. The first machine learning model may resemble a deep neural network, a Gaussian-based model, or any other MLIP-based model that is configured to learn charge transfers of an atomic system.

As shown in block 508, a given charge transfer may be referred to as a transfer of charge d between atom j and central atom i. This may be written as dᵢⱼ for respective charge transfers between respective atoms j and central atom i.

Once the charge transfers dᵢⱼ are learned, the total charge on a given atom within atoms j and central atom i may be defined as the sum over all neighbors of the charge transferred to that atom. Thus, a sum of atomic charges on central atom i, for example, may be written as qᵢ=Σ_{j∈N}_{ᵢ} dᵢⱼ−dⱼᵢ.

In some embodiments, the first machine learning model 506 may not be configured to learn charge transfers based on a principle dᵢⱼ=−dⱼᵢ. However the total charge transfer is still configured to be a local quantity that, by construction, maintains this principle. In other embodiments, the first machine learning model 506 is indeed configured to learn charge transfers based on the principle dᵢⱼ=−dⱼᵢ, thus still ensuring the same outcome.

Continuing with the workflow illustrated by architecture 500, the respective atomic charges of the atoms j and i within the atomic system are then used to generate an auxiliary Hamiltonian description of the atomic system. As shown in the figure, the auxiliary Hamiltonian description encompasses the analysis of both short-range and long-range effects, while also taking into account discontinuities and/or transitions as pertaining to the given atomic system.

In parallel to the process illustrated by atomic descriptors 502, embedding 504, learning 506, charge transfer 508, atomic charges 510, and auxiliary Hamiltonian 512, the process illustrated by atomic descriptors 516, embedding 518, learning 520, and local energies 522 is performed.

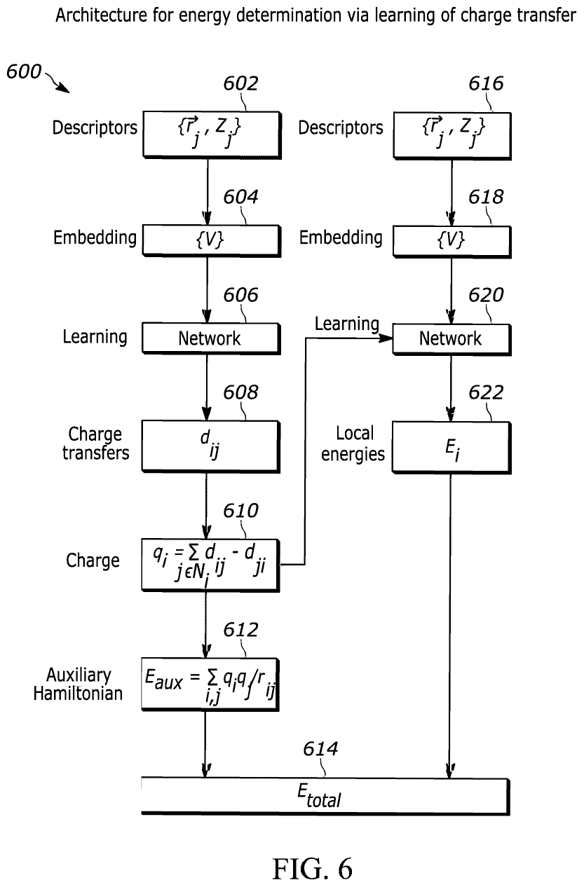

It should be understood that in embodiments depicted in FIG. 5, the sequence illustrated by 502, 504, 506, 508, 510 and 512 may happen in parallel with the sequence illustrated by 516, 518, 520, and 522, or in a sequential ordering. Embodiments illustrated in FIG. 6 also demonstrate a sequential ordering of process 600 and is additionally discussed below.

Similarly to atomic descriptors 502, atomic descriptors 516 include information pertaining to an atomic description of the atomic system, such as atomic positions and atomic species. Atomic descriptors 502 and 516 refer to the same atomic description of the same atomic system, and are illustrated separately for ease of workflow discussion within FIG. 5. Thus, atomic descriptors 516 are also local in a sense that they includes reference to atoms j within a neighborhood of a central atom i.

Atomic descriptors 516 are then embedded as inputs for the interatomic potentials, as illustrated in embedding 518.

The embedded atomic descriptors are then provided to a second machine learning model 520, wherein the second machine learning model 520 is executed in order to learn local energies 522. The second machine learning model may resemble a deep neural network, a Gaussian-based model, or any other MLIP-based model that is configured to learn local energies of an atomic system.

In some embodiments, the second machine learning model 520 may resemble a deep neural network, such as Allegro. The local energies 522 may then be written as Eᵢ=Σ_{j∈N}_{ᵢ} Eᵢⱼ for the central atom i, for example.

Following the determination of the auxiliary Hamiltonian description and the learning of the local energies of the atomic system, the total energy of the atomic system may then be determined. In some embodiments, the total energy determination is based on the strictly local energies that were learned via the second machine learning model 520, and on the analytical, auxiliary Hamiltonian description 512 that was determined via the first machine learning model 506. This ensures that the total energy determination accounts for both short-range and long-range effects.

In some embodiments, the determined atomic charges also be applied towards determining magnetic moments associated with the given atomic system. For example, if a given atomic system includes an atomic species of Manganese (Mn), architecture 500 may learn to label Mn in a 2+ state. From this, architecture 500 may be further configured to determine that a 2+ state means that there are 5 valence electrons, which can then be in a high-spin or low-spin state depending on the crystal field (e.g. if it is tetrahedral or octahedral site in an oxide).

Furthermore, related forces may also be computed as a summation of \vec{F}_{j,local}=ΣᵢdE_{i,local}/d\vec{r}ⱼ and the auxiliary \vec{\vec{F}}_{j,aux}=dEₐᵤₓ/d\vec{r}ⱼ. As the atomic charges are local due to the method of learned charge transfers, there will be a long-range analytical term

$${F}_{k , aux} \approx - {q}_{i} \frac{d}{d {r}_{k}} ( \frac{{q}_{k}}{{r}_{i k}} )$$

for atoms k that are not in the neighborhood of atom i, and a short-range term

$${F}_{j , aux} \approx - \frac{d}{d {r}_{j}} ( \frac{{q}_{i} {q}_{j}}{{r}_{i j}} )$$

for atoms j that are in the neighborhood of atom i.

In some embodiments, the output of architecture 500 may be any combination of energy, forces, stresses, polarizability, magnetic moment, point charges, electrostatic field, and/or any other atomic-system-wide and/or atom-specific property, which can be used in a simulation such as molecular dynamics, a structure or conformation search, a Monte Carlo simulation, or any other atomistic simulation. Similar outputs may be obtained using architectures 600 and 700, illustrated in the following figures.

FIG. 6 illustrates another workflow diagram for a machine-learning-based energy determination within the context of machine-learning interatomic potentials of an atomic system, according to some embodiments.

Similarly to that which is illustrated by process 500 in FIG. 5, process 600 demonstrates the use of atomic positions and species to determine a total energy of a given atomic system. Atomic descriptors 602 are embedded during embedding 604 as inputs for the interatomic potentials, and subsequently provided to a first machine learning model 606. As above with process 500, machine learning model 606 is executed in order to learn charge transfers 608. Then, once the charge transfers dᵢⱼ are learned, the total charge on a given atom within atoms j and central atom i may be defined as the sum over all neighbors of the charge transferred to that atom.

The atomic charges 610 are then used to determine an auxiliary Hamiltonian description 612 of the atomic system. As shown in the figure, the auxiliary Hamiltonian description encompasses the analysis of both short-range and long-range effects, while also taking into account discontinuities and/or transitions as pertaining to the given atomic system.

In parallel, the embedded atomic descriptors are also provided to a second machine learning model 618, as indicated by atomic descriptors 616 and embedding 618. As depicted in FIG. 6, the sequence of 602, 604, 606, 608, and 610 may occur in parallel to the embedding of the atomic description depicted with the sequence of 616 and 618. However, prior to executing machine learning model 620, atomic charges 610 are also provided as inputs. This may be advantageous in particular embodiments wherein providing the machine learning model with both atomic descriptors and atomic charges ensures a more robust model for learning local energies.

Similarly to that which is illustrated in FIG. 5, both the determined auxiliary Hamiltonian description 612 and the learned local energies 622 are then used to determine the total energy 614 of the atomic system and may, in some embodiments, be also used to determine forces, stresses, or some other physically meaningful value.

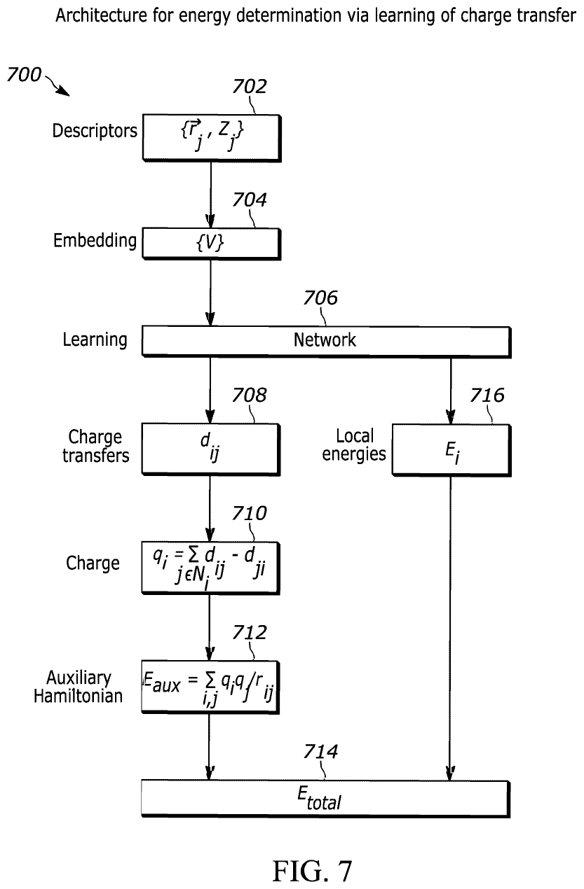

FIG. 7 illustrates yet another workflow diagram for a machine-learning-based energy determination within the context of machine-learning interatomic potentials of an atomic system, according to some embodiments.

As illustrated in architecture 700, atomic descriptors 702 include information pertaining to an atomic description of the atomic system, such as atomic positions and atomic species. In some embodiments, atomic descriptors 702 are local in a sense that they includes reference to atoms j within a neighborhood of a central atom i.

Atomic descriptors 702 are then embedded as inputs for the interatomic potentials, as illustrated in embedding 704.

The embedded atomic descriptors are then provided to a single machine learning model 706, wherein the machine learning model 706 is executed in order to learn both charge transfers 708 and local energies 716. Machine learning model 706 may resemble a deep neural network, a Gaussian-based model, or any other MLIP-based model that is configured to learn charge transfers of an atomic system.

As shown in block 708, a given charge transfer may be referred to as a transfer of charge d between atom j and central atom i. This may be written as dᵢⱼ for respective charge transfers between respective atoms j and central atom i.

Once the charge transfers dᵢⱼ are learned, the total charge on a given atom within atoms j and central atom i may be defined as the sum over all neighbors of the charge transferred to that atom. Thus, a sum of atomic charges on central atom i, for example, may be written as qᵢ=Σ_{j∈N}_{ᵢ}dᵢⱼ−dⱼᵢ.

In some embodiments, machine learning model 706 may not be configured to learn charge transfers based on a principle dᵢⱼ=−dⱼᵢ. However the total charge transfer is still configured to be a local quantity that, by construction, maintains this principle. In other embodiments, the first machine learning model 506 is indeed configured to learn charge transfers based on the principle dᵢⱼ=−dⱼᵢ, thus still ensuring the same outcome.

Continuing with the workflow illustrated by architecture 700, the respective atomic charges of the atoms j and i within the atomic system are then used to generate an auxiliary Hamiltonian description of the atomic system. As shown in the figure, the auxiliary Hamiltonian description encompasses the analysis of both short-range and long-range effects, while also taking into account discontinuities and/or transitions as pertaining to the given atomic system.

Following the determination of the auxiliary Hamiltonian description and the learning of the local energies of the atomic system, the total energy of the atomic system may then be determined. In some embodiments, the total energy determination is such that it accounts for both short-range and long-range effects.

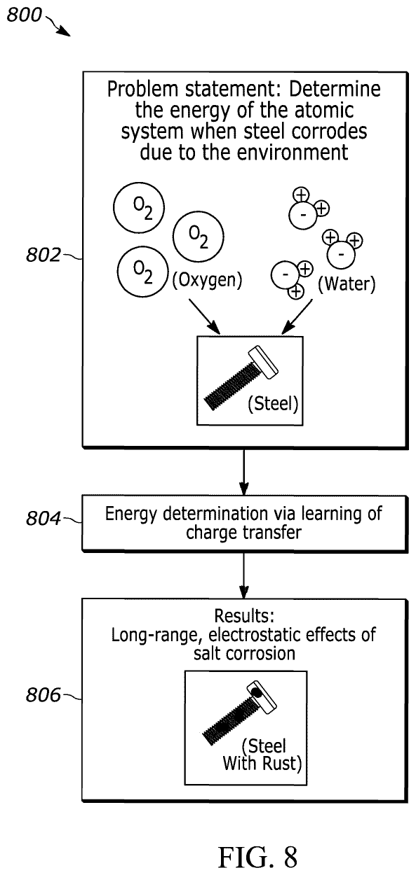

FIG. 8 illustrates an example implementation of applying a machine-learning-based energy determination to a scenario of corrosion of steel, according to some embodiments.

In the given scenario depicted in FIG. 8, process 800 describes an overall process of receiving a request from a customer to determine a property about an atomic system that is supposed to simulate effects of the corrosion of steel due to exposure to the environment. As shown in block 802, a problem statement, received from the customer in this scenario, requests for the determination of the total energy of a given atomic system in which steel is being exposed to typical environmental conditions. The environmental conditions are illustrated in block 802 via the oxygen and water.

Moreover, the “atomic system” shown in block 802 is illustrated as a steel nail, but it should be understood that should not be viewed as restrictive to the types of atomic systems the methods and computing systems herein may be applied to. It is meant for illustrative purposes and ease of discussion. Various other embodiments of a similar problem statement may relate to corrosion of a metal railing, etc. In addition, other embodiments of different problem statements, such as a request to determine the total energy following hydroscopic adsorption of water by a salt are also meant to be incorporated into the discussion herein.

In some embodiments, the customer may additionally provide the atomic positions pertaining to the crystalline lattice structure of the steel and the atomic species, which are understood to be iron, carbon, oxygen, and hydrogen from the problem statement.

In other embodiments, the customer provides merely the request to determine the total energy of the given atomic system, and methods and systems such as those described herein are configured to determine the atomic positions and species before providing such information to be embedded.

Subsequently, the atomic description, comprising the atomic positions and species, is provided to a system with an architecture such as that which is shown in FIG. 5, 6, or 7. Block 804 thus encompasses the embedding of the atomic description into inputs for the interatomic potentials, the providing of the embedded atomic descriptors to one or more machine learning models, and the learning of charge transfers and local energies based on those embedded atomic descriptors. As illustrated in the previous figures, the learned charge transfers are used to determine atomic charges and, subsequently, a resulting auxiliary Hamiltonian description of the atomic system.

In some embodiments, and as illustrated in FIG. 6, the charges, determined from learned charge transfers of a first deep neural network or Gaussian-based model, may be provided as an input, in addition to the embedded atomic descriptors being provided as input, to the second deep neural network or Gaussian-based model.

The auxiliary Hamiltonian description and the learned local energies may then be used to determine the request of the customer, such as the determination of the total energy of the atomic system. As shown in block 806, this may also be referred to as determining the total energy of the atomic system in order to deduce long-range, electrostatic effects of the corrosion of steel due to the environment.

The results of block 806 may then be provided to the customer, according to some embodiments. Block 804 may also encompass two or more iterations of a machine-learning-based energy determination, and thus the customer may receive information about results of one or more of those iterations.

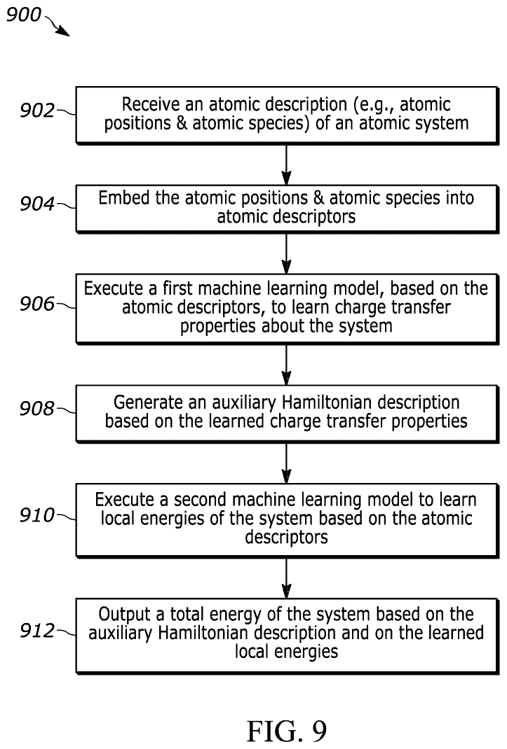

FIG. 9 is a flow diagram that illustrates a process of executing one or more machine learning models to learn charge transfers of an atomic system, and applying the learned charge transfers to determine long and short range effects of the atomic system, according to some embodiments.

Process 900 is provided within a context of receiving a specific problem statement from a customer and learning specific properties of a given atomic system. In some embodiments, process 900 may occur on one or more processors of a computing system, such as that which is described with respect to FIGS. 1 and 2. A user interface may also be provided via such a computing system, such that one or more customers may submit information regarding requests for MLIP-based simulations that are to be run on the computing system, and receive results of those request.

As shown in block 902, a customer may provide an atomic description of an atomic system, wherein the atomic description includes at least atomic positions and atomic species that are known to exist within the atomic system. The problem statement may further define certain objectives, such as the interest in using machine learning to determine an auxiliary Hamiltonian description of the atomic system, and/or the interest in having a description of the total energy of the atomic system, etc.

In block 904, the atomic description is embedded into inputs for the interatomic potentials.

The following blocks 906, 908, and 910 correspond to an architecture of a machine learning network in which two distinct machine learning models are executed in order to learn charge transfers and local energies of an atomic system, respectively. Such a process is illustrated in embodiments shown in FIGS. 5 and 6 herein. In other embodiments of process 900, an architecture of a machine learning network may instead correspond to FIG. 7 herein, in which a single machine learning model is executed in order to learn both charge transfers and local energies of an atomic system. Depending upon the type of problem statement provided by a customer in 902, or depending upon a certain type of complexity of the given atomic description, or depending upon a larger context of process 900 (e.g., the use of process 900 within iterations of an AIMD simulation, see also FIG. 10 herein), a given architecture from between FIGS. 5, 6, and 7 may be selected by the computing system in order to learn charge transfers and local energies of the particular atomic system.

The embeddings are then provided to a first machine learning model in block 906, wherein charge transfer properties about the atomic system are learned. The first machine learning model may resemble a deep neural network, a Gaussian-based model, or any other MLIP-based model that is configured to learn charge transfers of an atomic system.

In some embodiments, block 908 may then include two steps: the learned charge transfers are used to determine atomic charges of the atomic system, and the atomic charges are then used to generate an auxiliary Hamiltonian description of the given atomic system. Such an auxiliary Hamiltonian description is configured to describe both long-range and short-range effects of the atomic system, and also ensures charge neutrality at both local and global levels. It should be understood that depending upon the specific atomic description and problem statement, block 908 may include any method of utilizing learned charge transfers to generate an auxiliary Hamiltonian description, and that block 908 may indeed resemble the two step process of arriving at an auxiliary Hamiltonian description, but also any other number of steps required.

In block 910, the embedded atomic descriptors are also provided, either simultaneously or sequentially, to a second machine learning model to determine local energies of the atomic system. In some embodiments, the second machine learning model may resemble a deep neural network, a Gaussian-based model, or any other MLIP-based model that is configured to learn local energies of an atomic system. Moreover, atomic charges that are determined from the learned charge transfers, described in block 906, may also be provided as an input to the second machine learning model, according to some embodiments.

In block 912, a total energy of the atomic system is determined, using the auxiliary Hamiltonian description and the learned local energies.

Following the determination of the total energy of the atomic system, process 900 may be iterated through again. A number of iterations above the initial iteration may be determined based on the specific properties that are intended to be learned by the one or more machine learning models, or based on the complexity of the given problem statement, etc.

Once the total energy has been determined and/or convergence within a given threshold has been met, results of the charge-transfer-based energy determination are provided to the customer via a customer interface.

In some embodiments, process 900 may resemble a sub-process within a larger context. For example, once an auxiliary Hamiltonian description is determined using process 900, the auxiliary Hamiltonian may then be used as an input to another technique in order to determine a ground state of the atomic system. In another example, once a total energy of the atomic system is determined using process 900, backpropagation may be applied to the machine-learning-based energy determination architecture, such as those shown in FIGS. 5, 6, and 7, in order to also determine other properties such as related forces of the atomic system. In yet another example, computations of energy and forces, using process 900, may be iteratively incorporated into a molecular dynamics (MD) simulation.

FIG. 10 is a flow diagram that illustrates an iterative, molecular-dynamics-based processing, according to some embodiments. As indicated by the arrow between Update positions 1010 and Atomic positions 1002, process 1000 may be computed more than once. In addition, and as also illustrated by “Update partitioning,” “Update neighbor list,” and “Update charges,” one or more steps within process 1000 may be completed during each iteration, during every other iteration, during each N^{th} iteration, etc. The following paragraphs illustrate an example embodiment in which process 900 is being run for the first time.

In block 1002, atomic positions {\vec{r}} are enumerated for respective atoms within the given atomic system. As introduced above, a problem statement that has been provided by a customer may include an atomic description, such as information about atomic positions and atomic species within the atomic system of focus for the problem statement.

In block 1004, those atomic positions are partitioned into two or more processors, such as two or more of processors 204 that have access to memory 208, which stores the MLIP model. In some embodiments, processors 204 are configured to partition respective atomic positions such that adjacent atoms are partitioned onto the same processor. This may reduce the amount of Message Passing Interface (MPI) communications that need to take place during and/or between iterations of process 1000. As shown by the arrows, this partitioning may not need to be repartitioned every timestep of the simulation.

In block 1006, an atomic neighbor list is created of the set of all atoms j within the neighborhood of atom i. For example, the neighbor list may include all atoms within a cutoff radius re from atom i. As introduced above, atomic positions may be defined within atomic descriptors {\vec{r}ⱼ, Zⱼ}, such as in atomic descriptors 502, 516, 602, 616, and 702 for each atom j within the atomic system. As shown by the arrows, this neighbor list may not need to be regenerated every timestep of the simulation.

In block 1008, a charge list may be created based on learned charge transfers, and using the machine-learning-based energy determination, such as in those architectures described in FIGS. 5, 6, and 7. As shown by the arrows, these charges may not need to be regenerated every timestep of the simulation, because they may be relatively stable. In some embodiments, a charge rebalancing step is further performed here to ensure Σᵢqᵢ=Qₜₒₜₐₗ, wherein Qₜₒₜₐₗ is the assigned total charge of the system.

In block 1010, the total energy of the atomic system, E({\vec{r}, Zⱼ}), is determined again using the machine-learning-based energy determination, such as in those architectures described in FIGS. 5, 6 and 7 herein. As introduced above, the energy computation provides the atomic positions, species, charges, and/or other properties, and provides them to one or more machine learning models. The auxiliary Hamiltonian description and local energies are respectively learned, and then applied in order to calculate a total energy of the atomic system. In addition, the forces, \vec{F}₁({\vec{r}ⱼ, Zⱼ}), may also be computed, such as via backpropagation, and using the values of the local energies that have been learned by the neural network 520, 620, or 706.

In block 1012, the computed energies and forces are used as input to update the atomic positions, such as by using an integration scheme, like leapfrog integration.

As shown by the arrow between blocks 1012 and 1002, MPI then communicates results between respective ones of the processors used in the partitioning in order to implement updated atomic positions and/or updated total energy based on that particular iteration of process 1000.

As introduced above, process 1000 may be iterated through more than once, and blocks 1004, 1006, 1008, and/or 1010 may be updated during at least some of the subsequent iterations of process 1000. For example, and following the determination of updated atomic positions via blocks 1012 and 1002, partitioning of the atomic positions onto respective processors may be updated prior to proceeding with creating neighbor lists in block 1006. In some embodiments, the partitioning may be updated every N iterations, wherein N may equal a value such as 1000. In another example, and following the partitioning of atomic positions in block 1004, the atomic neighbor list in block 1006 may be updated. In some embodiments, the neighbor lists may be updated every M iterations, wherein M may equal a value such as 100. In yet another example, and following the creating of the neighbor lists in block 1006, charges may be updated. Similarly, charges may or may not be updated each and every iteration, depending upon the integration that was done to update positions 1012 during the previous iteration.

It should be understood that process 1000 may be repeated any given number of times according to convergence criteria that have been set, time limitations, computing power constraints, or any other number of implementation and/or customer specific criteria.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A computer-implemented method for executing a machine learning network for machine-learned interatomic potentials, comprising:
receiving data indicating an atomic description of an atomic system, wherein the atomic description comprises atomic positions and atomic species of respective atoms in the atomic system;
embedding the data indicating the atomic positions and the atomic species into atomic descriptors;
executing a first machine learning model, based on the embedded atomic descriptors, to learn charge transfers of the atomic system;
determining atomic charges of the atomic system based on the learned charge transfers;
generating an auxiliary Hamiltonian description of the atomic system, based on the determined atomic charges;
providing the embedded atomic descriptors as inputs to a second machine learning model;
executing the second machine learning model to learn local energies of the atomic system; and
outputting a total energy of the atomic system based on the auxiliary Hamiltonian description and on the learned local energies.

2. The computer-implemented method of claim 1, further comprising:
determining, based on the outputted total energy of the atomic system, related forces of the atomic system through backpropagation; and
outputting the related forces.

3. The computer-implemented method of claim 2, wherein:
the outputted total energy and the outputted related forces of the atomic system are provided for integration within a given iteration of a molecular dynamics simulation; and
the method further comprises:
receiving an indication that, during a subsequent iteration of the molecular dynamics simulation, one or more of the atomic positions have been updated with respect to the atomic positions within the atomic description;
embedding the updated atomic positions and the atomic species into updated atomic descriptors; and
re-executing the first and the second machine learning models, based on the updated embedded atomic descriptors, to output an updated total energy of the atomic system.

4. The computer-implemented method of claim 1, wherein the charge transfers are local charge transfers that, when summed across the atomic system, ensures charge neutrality.

5. The computer-implemented method of claim 1, wherein:
providing the determined atomic charges as additional inputs to the second machine learning model; and
executing the second machine learning model to learn the local energies of the atomic system, based on the embedded atomic descriptors and on the determined atomic charges.

6. The computer-implemented method of claim 1, wherein the first machine learning model is a deep neural network or is one or more Gaussian processes.

7. The computer-implemented method of claim 1, wherein the second machine learning model is a deep neural network or is one or more Gaussian processes.

8. A computer-implemented method for executing a machine learning network for machine-learned interatomic potentials, comprising:
receiving data indicating a request from a customer to determine a total energy of an atomic system, wherein the data comprises atomic positions and atomic species of respective atoms in the atomic system;
embedding the data indicating the atomic positions and the atomic species into atomic descriptors;
executing one or more machine learning models to learn charge transfers and local energies of the atomic system based on the embedded atomic descriptors; and
outputting a total energy of the atomic system based on the learned charge transfers and on the learned local energies; and
providing results of the request to the customer.

9. The computer-implemented method of claim 8, wherein:
the one or more machine learning models is a single machine learning model; and
the executing the one or more machine learning models comprises executing the single machine learning model to learn both the charge transfers and the local energies of the atomic system.

10. The computer-implemented method of claim 8, wherein:
the one or more machine learning models comprises a first machine learning model and a second machine learning model; and
the executing the one or more machine learning models comprises:
executing the first machine learning model to learn the charge transfers; and
executing the second machine learning model to learn the local energies.

11. The computer-implemented method of claim 10, further comprising:
determining atomic charges of the atomic system based on the learned charge transfers;
providing the determined atomic charges as additional inputs to the second machine learning model; and
executing the second machine learning model to learn the local energies based on the embedded atomic descriptors and on the determined atomic charges.

12. The computer-implemented method of claim 8, further comprising:
receiving, within the request, an indication to learn long-range, electrostatic effects of the atomic system; and
selecting, based on the indication, a deep neural network, a Gaussian-based model, or a combination of a deep neural network and a Gaussian-based model to be executed to learn the charge transfers and the local energies.

13. The computer-implemented method of claim 8, further comprising:
computing, using a density functional theory technique, additional data indicating variations of the atomic system, wherein the additional data comprises varied atomic positions and varied atomic species;
providing the varied atomic positions and the varied atomic species to be embedded into additional atomic descriptors; and
executing the one or more machine learning models to learn the charge transfers and the local energies of the atomic system additionally based on the embedded additional atomic descriptors.

14. The computer-implemented method of claim 8, further comprising:
determining atomic charges of the atomic system based on the learned charge transfers;
generating an auxiliary Hamiltonian description of the atomic system, based on the determined atomic charges; and
determining the total energy of the atomic system based on the learned charge transfers, the learned local energies, and the auxiliary Hamiltonian description.

15. The computer-implemented method of claim 8, further comprising:
determining, based on the outputted total energy of the atomic system, related forces of the atomic system through backpropagation; and
outputting the related forces.

16. The computer-implemented method of claim 15,
the outputted total energy and the outputted related forces of the atomic system are provided for integration within a given iteration of a molecular dynamics simulation; and
the method further comprises:
receiving an indication that, during a subsequent iteration of the molecular dynamics simulation, one or more of the atomic positions have been updated with respect to atomic positions within the atomic description;
embedding the updated atomic positions and the atomic species into updated atomic descriptors; and
re-executing the one or more machine learning models, based on the updated embedded atomic descriptors, to output an updated total energy of the atomic system.

17. A computer-implemented method for executing a machine learning network for machine-learned interatomic potentials, comprising:
receiving data indicating an atomic description of an atomic system, wherein the atomic description comprises atomic positions and atomic species of respective atoms in the atomic system;
embedding the data indicating the atomic positions and the atomic species into atomic descriptors;
providing the embedded atomic descriptors to a machine learning model;
executing the machine learning model to learn charge transfers of the atomic system and to learn local energies of the atomic system;
determining atomic charges of the atomic system based on the learned charge transfers;
generating an auxiliary Hamiltonian description of the atomic system, based on the determined atomic charges; and
outputting a total energy of the atomic system based on the auxiliary Hamiltonian description and on the learned local energies.

18. The computer-implemented method of claim 17, wherein the machine learning model is a deep neural network or is one or more Gaussian processes.

19. The computer-implemented method of claim 17, wherein the charge transfers are local charge transfers that, when summed across the atomic system, ensures charge neutrality.

20. The computer-implemented method of claim 17, wherein:
the atomic descriptors are inputs for interatomic potentials that describe the atomic system; and
the atomic descriptors are invariant or covariant with respect to a symmetry group of the atomic system.
